(19) United States
(12) Patent Application Publication
(10) Pub. No.: US 2026/0204329 A1
(43) Pub. Date: Jul. 16, 2026

(54) DATA WRITING METHOD AND MEMORY CONTROLLER

(71) Applicant: Hefei Kaimeng Technology Co., Ltd., Anhui (CN)

(72) Inventors: Yang Chen, Anhui (CN); Kuai Cao, Anhui (CN); Tsung-Lin Wu, Anhui (CN); Qiao ZHU, Anhui (CN); Dong Dong Yao, Anhui (CN); Dong Sheng RAO, Anhui (CN)

(73) Assignee: Hefei Kaimeng Technology Co., Ltd., Anhui (CN)

(21) Appl. No.: 19/393,482

(22) Filed: Nov. 18, 2025

(30) Foreign Application Priority Data
Jan. 15, 2025 (CN) 202510064946.2

(51) Int. Cl. G11C 16/34; G11C 16/10

(52) U.S. Cl. CPC G11C 16/3459; G11C 16/102; G11C 16/3418

(57) ABSTRACT

The present disclosure provides a data writing method and a memory controller, adapted for a rewritable non-volatile memory module having a plurality of memory cells. The method includes the following steps: First, obtaining original data from a host system. Then, performing a plurality of randomization operations on the original data to obtain a plurality of write data. Next, performing a first randomization verification operation on each of the write data to obtain a target write data from the plurality of write data, wherein the quality of randomization of the target write data is determined to be qualified. Finally, storing the target write data into a plurality of target memory cells among the plurality of memory cells. The present disclosure, through multiple randomization operations and a verification process, effectively improves the randomness and reliability of data storage, so as to enhance the overall performance and data security of the storage system.

### CROSS-REFERENCE TO RELATED APPLICATION

This application claims the priority benefit of China application serial no. 202510064946.2, filed on January 15, 2025. The entirety of the above-mentioned patent application is hereby incorporated by reference herein and made a part of this specification.

### BACKGROUND

### Technical Field

The present disclosure relates to the field of semiconductor storage technology, and more specifically, to a data writing method for a rewritable non-volatile memory module and a memory controller using the method.

### Description of Related Art

With the rapid development of information technology, non-volatile storage devices are increasingly used in various electronic products. In particular, 3D NAND flash memory has become the mainstream of current non-volatile storage technology due to its high storage density, low cost, and excellent performance. However, as the storage density continues to increase, problems of data reliability and interference between memory cells have also become more prominent.

To improve the reliability of data storage and reduce interference between cells, data randomization technology is widely used in NAND flash memory. Conventional data randomization methods typically use a single randomization algorithm, such as a simple XOR operation or a fixed permutation table. Although this method improves data distribution to a certain extent, its effectiveness is often unsatisfactory when facing the increasingly complex structure of 3D NAND flash memory.

Furthermore, the prior art generally lacks an effective verification mechanism for randomization results. Directly writing data without verifying the quality of randomization may result in an uneven distribution of certain data patterns in the memory, so as to affect storage performance and reliability. Particularly in high-density storage scenarios, improper data distribution may lead to problems such as read disturbance and write disturbance, thereby shortening the service life of the storage device.

### SUMMARY

An objective of the present disclosure is to solve the above-mentioned problems, by being able to perform a plurality of randomization operations and effectively verify the quality of randomization, to ensure that data written to the memory has good random distribution characteristics, so as to improve the reliability and performance of storage.

One or more embodiments of the present disclosure provide a data writing method for a rewritable non-volatile memory module having a plurality of memory cells. The method includes: obtaining original data from a host system; performing a plurality of randomization operations on the original data to obtain a plurality of write data; performing a randomization verification operation on each of the write data to obtain a target write data from the plurality of write data, wherein the quality of randomization of the target write data is determined to be qualified; and storing the target write data into a plurality of target memory cells among the plurality of memory cells.

One or more embodiments of the present disclosure provide a memory controller, adapted for a storage device configured with a rewritable non-volatile memory module, wherein the storage device is electrically connected to a host system. The memory controller includes: a memory interface control circuit, for electrically connecting to the rewritable non-volatile memory module, wherein the rewritable non-volatile memory module has a plurality of memory cells; and a processor, electrically connected to the memory interface control circuit. The processor is configured to: obtain original data from the host system; perform a plurality of randomization operations on the original data to obtain a plurality of write data; perform a randomization verification operation on each of the write data to obtain a target write data from the plurality of write data, wherein the quality of randomization of the target write data is determined to be qualified; and store the target write data into a plurality of target memory cells among the plurality of memory cells.

Based on the foregoing, the data writing method and the memory controller provided by the present disclosure have significant advantages in terms of improving the quality of data randomization, optimizing storage efficiency, and extending device lifespan. It provides an efficient, reliable, and adaptive solution for the data storage management of non-volatile storage devices.

To make the aforementioned more comprehensible, several embodiments accompanied with drawings are described in detail as follows.

### BRIEF DESCRIPTION OF THE DRAWINGS

The accompanying drawings are included to provide a further understanding of the disclosure, and are incorporated in and constitute a part of this specification. The drawings illustrate exemplary embodiments of the disclosure and, together with the description, serve to explain the principles of the disclosure.

FIG. 1 is a block diagram of a host system and a storage device according to an embodiment of the present disclosure.

FIG. 2 is a flowchart of a data writing method according to an embodiment of the present disclosure.

FIG. 3 is a schematic diagram of a randomization operation according to an embodiment of the present disclosure.

FIG. 4 is a schematic diagram of a three-dimensional circuit architecture of a plurality of memory cells of a rewritable non-volatile memory module according to an embodiment of the present disclosure.

FIG. 5 is a flowchart of a randomization verification operation according to an embodiment of the present disclosure.

### DESCRIPTION OF THE EMBODIMENTS

Reference will now be made in detail to the exemplary embodiments of the present disclosure, examples of which are illustrated in the accompanying drawings. Wherever possible, the same reference numerals are used in the drawings and the description to refer to the same or similar parts.

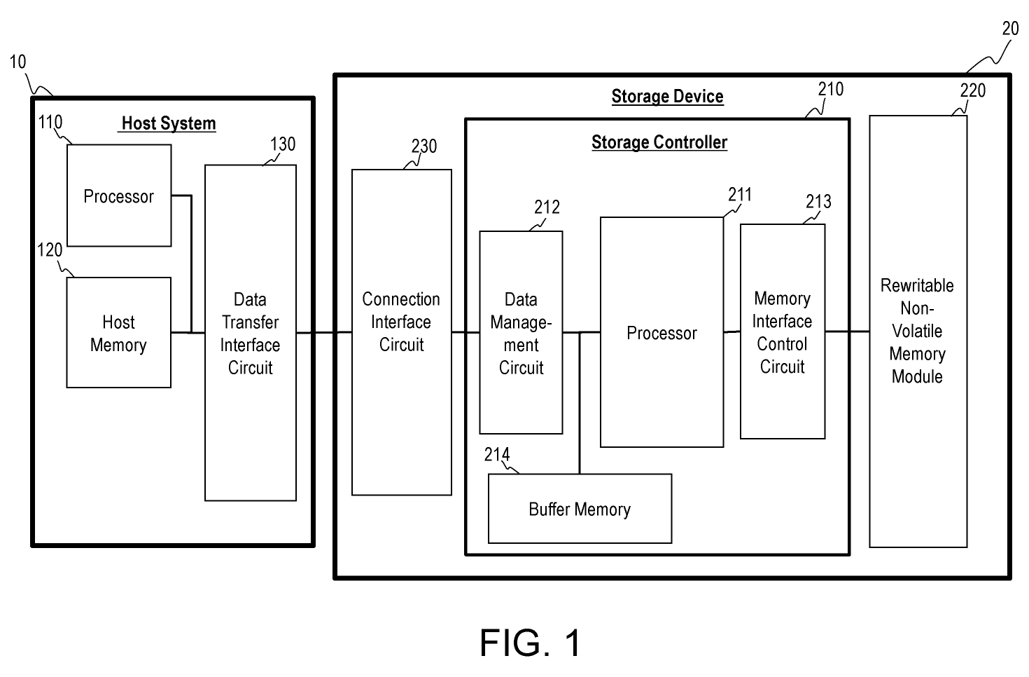

FIG. 1 is a block diagram of a host system and a storage device according to an embodiment of the present disclosure. Referring to FIG. 1, the host system 10 is, for example, a personal computer, a notebook computer, or a server. The host system 10 includes a processor 110 (also referred to as a second processor), a host memory 120, and a data transfer interface circuit 130. In this embodiment, the processor 110 is coupled (also referred to as electrically connected) to the host memory 120 and the data transfer interface circuit 130. In another embodiment, the processor 110, the host memory 120, and the data transfer interface circuit 130 are electrically connected to each other through a system bus. In this embodiment, the processor 110, the host memory 120, and the data transfer interface circuit 130 may be disposed on a motherboard of the host system 10. In this embodiment, the original data is, for example, user data transmitted from the host system 10 to the storage device 20, or data on which a randomization operation has not yet been performed.

The storage device 20 includes a memory controller 210, a rewritable non-volatile memory module 220, and a connection interface circuit 230. The memory controller 210 includes a processor 211 (also referred to as a first processor), a data management circuit 212, and a memory interface control circuit 213.

In this embodiment, the host system 10 is electrically connected to the storage device 20 through the data transfer interface circuit 130 and the connection interface circuit 230 of the storage device 20 to perform data access operations. For example, the host system 10 may store data to the storage device 20 or read data from the storage device 20 via the data transfer interface circuit 130.

In this embodiment, the number of the data transfer interface circuits 130 may be one or more. Through the data transfer interface circuit 130, a motherboard may be electrically connected to the storage device 20 via a wired or wireless manner. The storage device 20 may be, for example, a USB flash drive, a memory card, a solid state drive (SSD), or a wireless memory storage device. The wireless memory storage device may be, for example, a Near Field Communication (NFC) memory storage device, a Wi-Fi memory storage device, a Bluetooth memory storage device, or a Bluetooth Low Energy memory storage device (e.g., iBeacon), or other memory storage devices based on various wireless communication technologies. In addition, the motherboard may also be electrically connected to various I/O devices such as a Global Positioning System (GPS) module, a network interface card, a wireless transmission device, a keyboard, a screen, and a speaker through the system bus.

In this embodiment, the data transfer interface circuit 130 and the connection interface circuit 230 are interface circuits compatible with the Peripheral Component Interconnect Express (PCI Express) standard. Moreover, data transmission between the data transfer interface circuit 130 and the connection interface circuit 230 is performed using the Non-Volatile Memory express (NVMe) communication protocol.

In addition, in another embodiment, the connection interface circuit 230 may be packaged in a single chip with the memory controller 210, or the connection interface circuit 230 is disposed outside a chip that includes the memory controller 210.

In this embodiment, the host memory 120 is used to temporarily store instructions or data executed by the processor 110. For example, in this embodiment, the host memory 120 may be a dynamic random access memory (DRAM), a static random access memory (SRAM), or the like. However, it should be understood that the present disclosure is not limited thereto, and the host memory 120 may also be other suitable types of memory.

The memory controller 210 is used to execute a plurality of logic gates or control instructions implemented in a hardware form or a firmware form, and to perform operations such as data writing, reading, and erasing in the rewritable non-volatile memory module 220 according to instructions from the host system 10.

More specifically, the processor 211 in the memory controller 210 is a hardware with computing capabilities, used to control the overall operation of the memory controller 210. Specifically, the processor 211 is programmed by a plurality of control instructions/program codes, and when the storage device 20 is in operation, these control instructions/program codes are executed to perform operations such as data writing, reading, and erasing. In addition, in this embodiment, the control instructions/program codes may be further executed to perform a data writing operation, a randomization verification operation, or a randomization operation, to implement the data writing method provided by the present disclosure. The control instructions/program codes corresponding to the data writing method may be further implemented as circuit units in a hardware form to implement the data writing method provided by the present disclosure.

It is worth mentioning that, in this embodiment, the processor 110 and the processor 211 are, for example, a central processing unit (CPU), a micro-processor, or another programmable processing unit, a digital signal processor (DSP), a programmable controller, an application-specific integrated circuit (ASIC), a programmable logic device (PLD), or other similar circuit components, and the present disclosure is not limited thereto.

In this embodiment, as described above, the memory controller 210 further includes the data management circuit 212 and the memory interface control circuit 213. It should be noted that operations performed by the various components of the memory controller 210 may also be regarded as operations performed by the memory controller 210.

The data management circuit 212 is electrically connected to the processor 211, the memory interface control circuit 213, and the connection interface circuit 230. The data management circuit 212 is configured to perform data transmission according to instructions received from the processor 211. For example, it reads data from the host system 10 (e.g., the host memory 120) via the connection interface circuit 230, and writes the read data to the rewritable non-volatile memory module 220 via the memory interface control circuit 213 (e.g., performing a write operation according to a write command from the host system 10). As another example, it reads data from one or more physical units of the rewritable non-volatile memory module 220 via the memory interface control circuit 213 (the data may be read from one or more memory cells in one or more physical units), and writes the read data to the host system 10 (e.g., the host memory 120) via the connection interface circuit 230 (e.g., performing a read operation according to a read command from the host system 10). In another embodiment, the data management circuit 212 may also be integrated into the processor 211.

The memory interface control circuit 213 is used to receive instructions from the processor 211 and cooperate with the data management circuit 212 to perform a writing (also referred to as programming) operation, a reading operation, or an erasing operation on the rewritable non-volatile memory module 220.

In addition, data to be written to the rewritable non-volatile memory module 220 is converted by the memory interface control circuit 213 into a format acceptable to the rewritable non-volatile memory module 220. Specifically, if the processor 211 is to access the rewritable non-volatile memory module 220, the processor 211 sends corresponding instruction sequences to the memory interface control circuit 213 to instruct the memory interface control circuit 213 to perform corresponding operations. For example, these instruction sequences may include a write instruction sequence for instructing to write data, a read instruction sequence for instructing to read data, an erase instruction sequence for instructing to erase data, and corresponding instruction sequences for instructing various memory operations. These instruction sequences may include one or more signals, or data on a bus. These signals or data may include instruction codes or program codes. For example, a read instruction sequence will include information such as a read identifier, a memory address, and a physical address.

In addition, the memory controller 210 establishes a logical-to-physical address mapping table and a physical-to-logical address mapping table to record mapping relationships between logical addresses of logical units (e.g., logical blocks, logical pages) allocated to the rewritable non-volatile memory module 220 and physical addresses of physical units (e.g., physical erase units/physical blocks, physical pages). In other words, the memory controller 210 may look up a physical unit mapped by a logical unit through the logical-to-physical address mapping table (also referred to as a logical-to-physical mapping table) (e.g., look up a physical page mapped by a logical page; look up a physical address mapped by a logical address), and may look up a logical unit mapped by a physical unit through the physical-to-logical address mapping table (also referred to as a physical-to-logical mapping table) (e.g., look up a logical page mapped by a physical page; look up a logical address mapped by a physical address).

In an embodiment, the memory controller 210 further includes a buffer memory 214. The buffer memory is electrically connected to the processor 211 and is used to temporarily store data and instructions from the host system 10, data from the rewritable non-volatile memory module 220, or other system data for managing the storage device 20 (e.g., various mapping tables, index tables, various information or data related to the randomization operation and the randomization verification operation), so that the processor 211 may quickly access the data, instructions, or system data from the buffer memory 214. In an embodiment, the memory controller 210 may establish one or more write mapping tables in the buffer memory 214 to indicate target physical addresses for writing valid data. It should be noted that, in other embodiments, the buffer memory 214 may also be configured outside the memory controller 210. Alternatively, the buffer memory 214 may be configured both inside and outside the memory controller 210.

The rewritable non-volatile memory module 220 is electrically connected to the memory controller 210 (the memory interface control circuit 213) and is used to store user data sent by the host system 10.

In this embodiment, each memory die (chip) of a plurality of memory dies of the rewritable non-volatile memory module 220 has a plurality of planes, and each plane has a plurality of physical blocks. Each physical block includes a plurality of physical programming units (also referred to as physical pages). Each physical page has a plurality of memory cells (also referred to as physical bytes or bytes), and each memory cell corresponds to a physical address. A physical address is used to record the physical location of data stored in a memory cell. It should be noted that the present disclosure does not limit the size of each physical page and logical page.

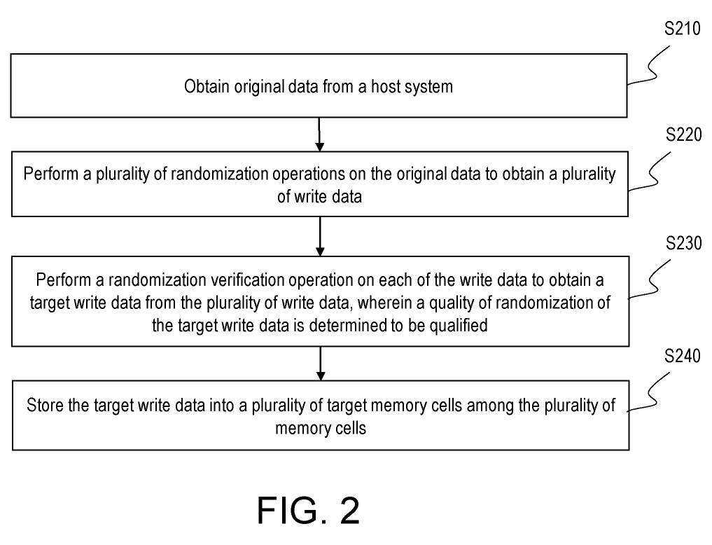

FIG. 2 is a flowchart of a data writing method according to an embodiment of the present disclosure.

Referring to FIG. 2, in step S210, the memory controller 210 (the processor 211) obtains original data from the host system 10. Then, in step S220, the processor 211 performs a plurality of randomization operations on the original data to obtain a plurality of write data.

In an embodiment, the processor 211 performs a randomization operation on original data to obtain write data, wherein the randomization operation is used to change a distribution pattern of a first bit value and a second bit value in the original data, such that an arrangement of the first bit value and the second bit value in the write data exhibits a random distribution characteristic, wherein the first bit value and the second bit value respectively correspond to "0" and "1" in binary data. After performing the randomization operation, the processor 211 stores the obtained write data into the buffer memory 214.

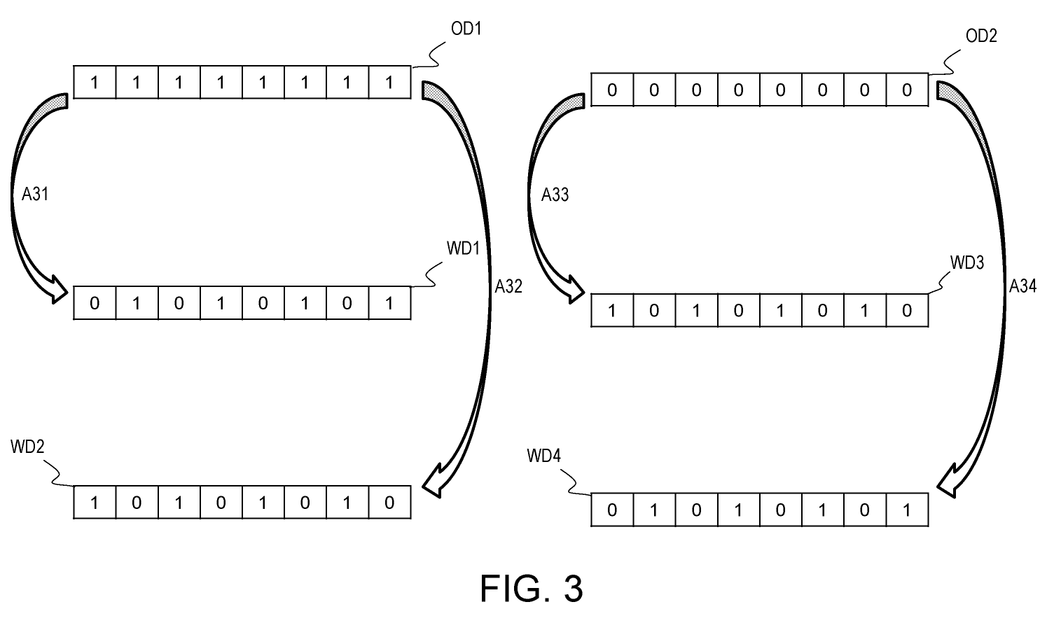

FIG. 3 is a schematic diagram of a randomization operation according to an embodiment of the present disclosure. For example, the randomization operation of the present disclosure may be further explained through a specific example. As shown in FIG. 3, the figure illustrates a process of performing a randomization operation on original data. In this example, two groups of original data, OD1 and OD2, are considered, with each group containing 8 bits.

OD1 is composed of 8 consecutive "1"s (11111111), while OD2 is composed of 8 consecutive "0"s (00000000). These two groups of data represent a non-random distribution in an extreme case, where the distribution of the first bit value ("0") and the second bit value ("1") is highly concentrated. The original data is, for example, user data to be stored in the storage device 20 by the host system 10.

By performing the randomization operation, corresponding write data WD1, WD2, WD3, and WD4 are obtained. Specifically:

After OD1 undergoes a (first) randomization operation A31, WD1 (01010101) is generated.

After OD1 undergoes another (second) randomization operation A32, WD2 (10101010) is generated.

After OD2 undergoes a (third) randomization operation A33, WD3 (10101010) is generated.

After OD2 undergoes another (fourth) randomization operation A34, WD4 (01010101) is generated.

The results show that regardless of whether the original data is all "1"s or all "0"s, the write data obtained after the randomization operation exhibits a pattern of "0"s and "1"s appearing in a uniformly alternating manner. This pattern significantly changes the original distribution of the first bit value and the second bit value in the original data, causing the arrangement of "0"s and "1"s in the write data to exhibit a more random distribution characteristic.

It is worth noting that, although the write data in this example exhibits a regular alternating pattern, this is only for simplification of the description. In practical applications, the result of a randomization operation usually generates a more complex and irregular bit distribution to ensure the security of data stored in the storage device.

Through this example, it may be clearly seen how a randomization operation effectively changes the distribution pattern of bit values in the original data, so as to achieve the purpose of data randomization. This randomization not only improves the uniformity of data storage, thereby preventing write disturbance that would otherwise be caused by a non-uniform distribution of bit values, but also enhances data security.

More specifically, in an embodiment, the process of performing a plurality of randomization operations on the original data may use different randomization algorithms to process the original data, wherein the different randomization algorithms include at least one of the following:

(1) XOR operation: A system (e.g., the processor 211) predefines a plurality of random sequences of different lengths, which are stored in a look-up table. A random sequence of an appropriate length is selected according to a size of the original data. If a length of the original data exceeds that of the random sequence, the random sequence is used cyclically. When performing the XOR operation, each bit of the original data is XORed with a corresponding bit of the random sequence to generate a first type of write data.

(2) Shift operation: The system maintains a shift amount pool containing different circular shift and logical shift values. When performing a shift operation on the original data, a value is selected from the shift amount pool to shift the entire data block. For a large data block, it may be divided into segments of a fixed size, each segment uses a different shift amount, and then they are recombined to generate a second type of write data.

(3) Permutation operation: The system predefines a plurality of permutation tables, with each permutation table defining a different bit reordering scheme. A permutation table is selected, and bits in the original data are rearranged according to an order defined in the table. For a large data block, it may be divided into blocks of a fixed size, each block uses a different permutation table, and then they are recombined to generate a third type of write data.

(4) Dynamic random seed operation: The system collects a plurality of system variables as input for a random seed, including but not limited to: a system time (including a local time of the host system 10 or the storage device 20), a data address, a temperature sensor reading, a power supply voltage fluctuation value, an operating frequency of the memory controller 210, a number of recent data read/write operations, a unique identifier of the storage device 20, a process ID or a thread ID of the host system 10, a MAC address of a network interface (if available), a current remaining capacity of the storage device 20, an operating time since a last power-on, a value of an internal error counter of the storage device 20, etc. The system may select one of the variables as the seed, or combine a plurality of variables to generate a more complex seed. For example, a composite seed may be generated by combining the system time, the temperature reading, and the error counter value through a bitwise operation. This seed is used to initialize a pseudo-random number generator (such as a linear congruential generator or a Mersenne Twister algorithm) to generate a random sequence. Then, this random sequence is used to transform the original data (such as through an XOR operation or a bitwise addition) to generate a fourth type of write data.

(5) Grouping operation: The original data is divided into a plurality of sub-blocks, wherein a size of each sub-block may be fixed (e.g., 4KB) or dynamically determined (e.g., based on an entropy value of the data). For each sub-block, the system selects one or more of the four operations described above for combined application. For example:

A first sub-block may first undergo an XOR operation, and then a shift operation.

A second sub-block may first undergo a permutation operation, and then use a dynamic random seed operation.

A third sub-block may undergo only a dynamic random seed operation.

After all the sub-blocks are processed, they are recombined to form a fifth type of write data.

Through these five different randomization operations, the system generates five different types of write data. This diversified randomization strategy increases the randomness of the data, making the distribution of bit states of the bit values of the finally generated write data more uniform.

Returning to FIG. 2, next, in step S230, the processor 211 performs a randomization verification operation on each of the write data to obtain a target write data from the plurality of write data, wherein a quality of randomization of the target write data is determined to be qualified.

Before describing the details of the randomization verification operation, a three-dimensional circuit architecture of the plurality of memory cells of the rewritable non-volatile memory module 220 is first described, wherein the plurality of memory cells are regarded as being configured at intersections of M first reference lines corresponding to an X direction, P second reference lines corresponding to a Y direction, and Q third reference lines corresponding to a Z direction.

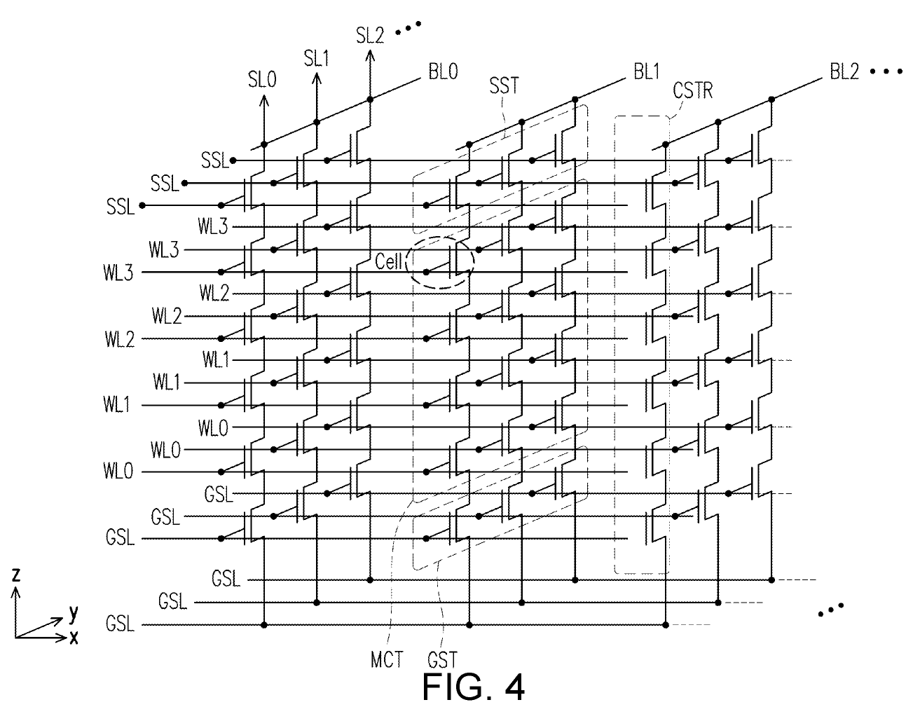

FIG. 4 is a schematic diagram of a three-dimensional circuit architecture of a plurality of memory cells of a rewritable non-volatile memory module according to an embodiment of the present disclosure. The structure includes a plurality of key components, forming a complex three-dimensional memory array. Taking a NAND-type rewritable non-volatile memory module as an example, the specific structure is as follows:

Word Line (WL): Labeled as WL0, WL1, WL2, and WL3 in the figure, arranged horizontally along an x-axis direction. Each plane has a plurality of parallel word lines for selecting memory cells of a specific layer. The word lines may be regarded as first reference lines corresponding to the X direction (also referred to as a first direction).

Bit Line (BL): Labeled as BL0, BL1, BL2, etc., in the figure, arranged vertically along a y-axis direction. The bit lines may be regarded as second reference lines corresponding to the Y direction (also referred to as a second direction).

Cell String (CSTR): Is a physical structure that includes a series of vertically stacked memory cells, as well as a SST at the top and a GST at the bottom. It represents a complete vertical NAND string in the three-dimensional memory array and is a basic building block of the memory array.

String Line (SL): Labeled as SL0, SL1, SL2, etc., in the figure, arranged vertically along a z-axis direction. Each string line includes a series of vertically stacked memory cells, forming a NAND string structure. The string lines may be regarded as third reference lines corresponding to the Z direction (also referred to as a third direction). The CSTR (Cell String) in the present disclosure refers to a complete vertical structure including a series of vertically stacked memory cells as well as the SST at the top and the GST at the bottom. The vertical stack of memory cells within the CSTR may be referred to as a string line (String Line).

Source Select Line (SSL): Located at the top of a NAND string, used to control a source select transistor (SST).

Ground Select Line (GSL): Located at the bottom of a NAND string, used to control a ground select transistor (GST).

Common Source Line (CSL): Located at the very bottom, providing a common source connection for all NAND strings.

Memory Cell Transistor (MCT): Labeled as MCT in the figure, is a unit that actually stores data.

Source Select Transistor (SST): Located at the top of each NAND string, controlled by the SSL.

Ground Select Transistor (GST): Located at the bottom of each NAND string, controlled by the GSL.

In simple terms, in this three-dimensional structure, the references for the three directions are:

X direction: word line (WL), the first reference line;

Y direction: bit line (BL), the second reference line;

Z direction: string line (SL), the third reference line.

An intersection of these three types of reference lines is configured as a memory cell (labeled as "Cell" in the figure). Each memory cell is located at an intersection of a specific WL, BL, and SL, and is capable of independently storing and accessing data. This three-dimensional structure significantly increases storage density, allowing more memory cells in the same chip area. It should be noted that these three directions are mutually perpendicular.

In an embodiment, the processor 211 obtains a plurality of bit values of each write data, wherein each of the plurality of bit values is one of N preset bit states. In the present disclosure, a memory cell of a non-volatile storage device may be configured to store different numbers of bits of data. The number of bits that each memory cell is capable of storing may vary according to specific application requirements and technical implementations, ranging from 1 bit to multiple bits. They are divided into a plurality of types: SLC (Single-Level Cell); MLC (Multi-Level Cell); TLC (Triple-Level Cell); QLC (Quad-Level Cell); and PLC (Penta-Level Cell).

Specifically, a single memory cell may be programmed to have 2^{X}different threshold voltage states, wherein X is the number of bits that the memory cell is configured to store. For example, when X=1, a memory cell has 2 bit states and may store 1 bit of data (SLC); when X=2, a memory cell has 4 bit states (MLC) and may store 2 bits of data; when X=3, a memory cell has 8 bit states and may store 3 bits of data (TLC); when X=4, a memory cell has 16 bit states and may store 4 bits of data (QLC); and when X=5, a memory cell has 32 bit states and may store 5 bits of data (PLC). and so on. This method allows a storage device to achieve different storage densities under the same physical structure, so as to strike a balance between capacity, performance, and reliability.

Taking TLC (Triple-Level Cell) flash memory as an example, each memory cell may store 3 bits of information/data, corresponding to 8 bit states (N=8), which are usually denoted as S0, S1, S2, S3, S4, S5, S6, and S7. The processor 211 reads a voltage level of each memory cell and converts it into a corresponding bit state. For example, a voltage level of a certain memory cell may correspond to state S3.

The following describes implementations of the randomization verification operation of the present disclosure through a plurality of embodiments.

Embodiment 1: Obtaining N state percentages of the N bit states corresponding to the write data.

For example, in an embodiment, it is assumed that the memory cells are SLC, that is, X=1, and N=2¹=2.

Initially, the processor 211 obtains a plurality of bit values of the write data. It is assumed that the obtained write data is the eight bits "10110101".

Next, the processor 211 obtains the state percentages of the N bit states.

In this example, N=2, which represents two states, for example, S0=0 and S1=1, and their respective counts are 3 and 5.

Next, the processor 211 divides the count of each bit state by the total number of bits to obtain the following:

State percentage of bit state S0(0): 3/8 = 37.5%;

State percentage of bit state S1(1): 5/8 = 62.5%.

Next, the processor 211 obtains the quality of randomization:

In this simple embodiment, the processor 211 may preliminarily determine the quality of randomization by comparing the percentages of the two states. If a difference between the percentages of the two bit states is small, the quality of randomization is considered to be good. For example, if a difference value between the two state percentages is less than a preset threshold value, it may be determined that the difference between the percentages of the two states is small, indicating that the quality of randomization is good.

Embodiment 2: Introducing a baseline percentage value.

In this embodiment, a concept of a baseline percentage value is introduced and used to evaluate the quality of randomization.

A baseline percentage value corresponding to a given memory cell type is calculated as 100% divided by the total number of corresponding bit states. For example, taking MLC (Multi-Level Cell) as an example, X=2, N=2²=4, and the baseline percentage value is 100%/4=25%.

Initially, the processor 211 obtains a plurality of bit values of the write data. Here, it is assumed that the write data is "1001101110100011".

Next, the processor 211 obtains the state percentages of the N bit states. In this example, N=4, which represents four bit states: 00, 01, 10, and 11.

Next, the processor 211 divides the count of each bit state by the total number of bits, and the following may be calculated: State percentage of bit state S0(00): 3/8 = 37.5%; State percentage of bit state S1(01): 2/8 = 25%; State percentage of bit state S2(10): 2/8 = 25%; State percentage of bit state S3(11): 1/8 = 12.5%.

Next, the processor 211 obtains the baseline percentage value. Ideally, the state percentage of each of the 4 bit states should be equal, namely 100%/4=25%.

Finally, the processor 211 obtains the quality of randomization:

For example, the processor 211 compares the actual state percentages with the baseline percentage value to evaluate the quality of randomization. An average deviation or other statistical methods may be used to quantify the quality of randomization.

For example, the processor 211 may determine the quality of randomization through the state percentage of each bit state and the baseline percentage value via the following algorithms:

### 1. Average deviation method

The processor 211 calculates an absolute deviation between each state percentage and the baseline percentage value, and then takes an average value: |S0 deviation| = |37.5% - 25%| = 12.5%; |S1 deviation| = |25% - 25%| = 0%; |S2 deviation| = |25% - 25%| = 0%; |S3 deviation| = |12.5% - 25%| = 12.5%; Average deviation = (12.5% + 0% + 0% + 12.5%) / 4 = 6.25%.

The processor 211 may set a threshold, for example, 5%. If the average deviation is less than or equal to this threshold, the quality of randomization is determined to be qualified; otherwise, it is determined to be unqualified.

### 2. Maximum deviation method

The processor 211 finds a maximum value among all the deviations: Maximum deviation = max(12.5%, 0%, 0%, 12.5%) = 12.5%.

The processor 211 may set a corresponding threshold (also referred to as a first preset threshold), for example, 10%. If the maximum deviation is not greater than this threshold, the quality of randomization is determined to be qualified; otherwise, it is determined to be unqualified.

### 3. Standard deviation method

The processor 211 calculates a standard deviation of the state percentages: Average percentage (baseline percentage value) = (37.5% + 25% + 25% + 12.5%) / 4 = 25%; Standard deviation = sqrt([(37.5% - 25%)^2 + (25% - 25%)^2 + (25% - 25%)^2 + (12.5% - 25%)^2] / 4) ≈ 9.01%.

The processor 211 may set a corresponding threshold, for example, 8%. If the standard deviation is less than or equal to this threshold, the quality of randomization is determined to be qualified; otherwise, it is determined to be unqualified.

### 4. Entropy value method

The processor 211 calculates an entropy value of the state distribution to measure randomness: Entropy = -Σ(Pi * log2(Pi)) = -(0.375 * log2(0.375) + 0.25 * log2(0.25) + 0.25 * log2(0.25) + 0.125 * log2(0.125)) ≈ 1.91; Maximum entropy (completely random state) = log2(N) = log2(4) = 2; Relative entropy = Actual entropy / Maximum entropy = 1.91 / 2 ≈ 0.955.

The processor 211 may set a corresponding threshold, for example, 0.9. If the relative entropy is greater than or equal to this threshold, the quality of randomization is determined to be qualified; otherwise, it is determined to be unqualified.

Through these different statistical methods, the processor 211 may comprehensively evaluate the quality of randomization of each write data.

Once a write data is determined to have a qualified quality of randomization, the processor 211 may use this write data as the target write data.

In an embodiment, after the processor 211 obtains a target write data, it does not need to perform the randomization verification operation on other write data, so as to save system resources.

However, in another embodiment, the processor 211 may perform the randomization verification operation on all the write data to find the write data with a qualified and best quality of randomization (e.g., with a minimum maximum deviation value) to serve as the target write data, so as to further improve the reliability and security of data storage of the storage device 20.

Returning to FIG. 2, after obtaining the target write data, next, in step S240, the processor 211 stores the target write data into a plurality of target memory cells among the plurality of memory cells of the rewritable non-volatile memory module 220. More specifically, the processor 211 assigns physical addresses of a plurality of target memory cells to the target write data, and after the target write data is programmed to the physical addresses, updates corresponding mapping information. In addition, this process may involve a wear-leveling algorithm of a flash memory controller to ensure that the usage counts of the memory cells are balanced, thereby extending the service life of the storage device.

On the other hand, the processor 211 generates and stores metadata related to the target write data, and this metadata is associated with subsequent read and recovery operations. In an embodiment, the metadata includes one or more of the following:

a. Randomization algorithm identifier: configured to identify the randomization algorithm used when generating the target write data, for a subsequent de-randomization operation.

b. Data mapping table: configured to record a correspondence relationship between data blocks and physical memory cell addresses.

c. Error correction code (ECC): configured to detect and correct bit errors that may occur.

d. Timestamp: configured to record a time when the data was written, for data version control and recovery.

e. Data length: configured to record a length of the original data, for a subsequent de-randomization operation.

f. Checksum: configured to verify data integrity.

In an embodiment, when the memory controller 210 receives a read command from the host system 10, the processor 211 performs the following steps to recover the original data:

(1) Parse read command: The processor 211 parses the read command from the host system 10 to determine a logical address range of the data to be read by the read command.

(2) Address translation: The processor 211 uses a logical-to-physical mapping table to translate the logical address into a corresponding physical address.

(3) Read metadata: The processor 211 first reads metadata related to the target data. This metadata is usually stored in a predefined special page or block and includes:

a. Randomization algorithm identifier;

b. Data mapping table;

c. Error correction code (ECC);

d. Data length;

e. Checksum.

(4) Read randomized data: According to the data mapping table in the metadata, the processor 211 reads the randomized target write data from a corresponding physical address.

(5) Error checking and correction: The processor 211 uses the read ECC information to perform error checking on the data. If a correctable error is found, it is corrected. If an uncorrectable error is found, the data block is marked as erroneous, and an attempt is made to use other recovery mechanisms.

Data integrity verification: In an embodiment, the processor 211 also uses the stored checksum to verify the integrity of the read data. If the check fails, it may be necessary to initiate a data recovery procedure or report an error to the host system.

(7) Determine de-randomization algorithm: After successfully decoding the target write data, the processor 211 determines the de-randomization algorithm to be used according to the randomization algorithm identifier in the metadata.

(8) Perform de-randomization operation: The processor 211 performs a de-randomization operation on the read randomized data. This process is an inverse process of the randomization operation during writing, and may include:

a. Inverse shift operation;

b. Inverse operation of XOR operation;

c. Inverse permutation operation;

d. Using the same random seed for an inverse operation.

(9) Data length adjustment: In an embodiment, the processor 211 may also trim the de-randomized data according to the original data length recorded in the metadata, ensuring that a length of the recovered data is consistent with the original data.

(10) Data transmission: After obtaining the corresponding original data, the processor 211 transmits the recovered original data to the host system 10 through the connection interface circuit 230 in response to the read command.

This detailed de-randomization process enables the memory controller 210 to accurately recover the randomized target write data stored in the storage device 20 into the corresponding original data, and securely transmit it to the host system 10. This process not only ensures the correct recovery of data, but also includes steps such as error detection, correction, and data integrity verification to improve the reliability and correctness of data reading. It should be noted that the randomization operation and the de-randomization operation may be implemented through a specific randomization circuit and a de-randomization circuit to carry out the aforementioned randomization/de-randomization algorithms. In addition, the randomization circuit and the de-randomization circuit may also be integrated into a single circuit unit.

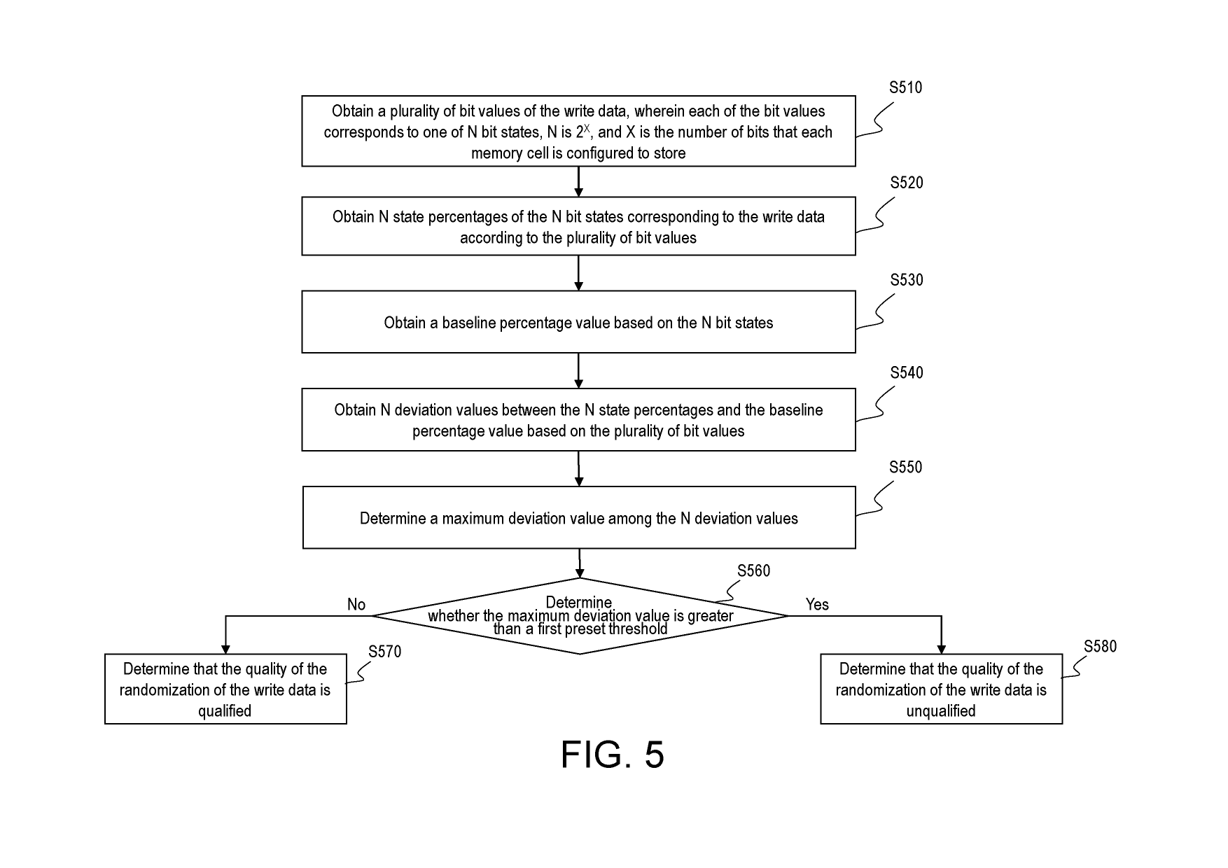

FIG. 5 is a flowchart of a randomization verification operation according to an embodiment of the present disclosure.

Referring to FIG. 5, this embodiment describes a method for verifying the quality of randomization of write data, adapted for a rewritable non-volatile memory module having a plurality of memory cells. The method is executed by a processor of a memory controller and mainly includes the following steps:

Obtain bit values (step S510):

The processor obtains a plurality of bit values of the write data, wherein each bit value corresponds one of N bit states, wherein N=2^{X}, and X is the number of bits that each memory cell is configured to store. For example, for MLC (Multi-Level Cell) flash memory, X=2 and N=2²=4, which means that each memory cell may store 2 bits of data and has 4 possible states.

Calculate state percentages (step S520):

The processor calculates N state percentages of the N bit states corresponding to the write data according to the obtained plurality of bit values. For example, for MLC flash memory, the possible states are 00, 01, 10, and 11, and the processor calculates a percentage of each state in the write data.

Obtain baseline percentage value (step S530):

The processor obtains a baseline percentage value based on the N bit states. Ideally, the percentage of each state should be equal, that is, the baseline percentage value is 1/N. For example, for MLC flash memory, the baseline percentage value is 25%.

Calculate deviation values (step S540):

The processor calculates N deviation values between the N state percentages and the baseline percentage value based on the plurality of bit values. This step quantifies a degree of data randomization by comparing the actual state percentages with the ideal state percentages.

Determine maximum deviation value (step S550):

The processor determines a maximum deviation value among the N deviation values. This maximum deviation value represents a degree to which the data distribution deviates from an ideal random state.

Determine quality of randomization (steps S560, S570, S580):

The processor compares the maximum deviation value with a preset threshold:

a) If the maximum deviation value is not greater than a first preset threshold, the quality of randomization of the write data is determined to be qualified (step S570).

b) If the maximum deviation value is greater than the first preset threshold, the quality of randomization of the write data is determined to be unqualified (step S580).

In another embodiment, when it is determined that the maximum deviation value is greater than the first preset threshold, the processor 211 may perform a further determination to determine an overall degree of deviation of the state percentages. For example, if the maximum deviation value is greater than the first preset threshold, in addition to determining that the quality of randomization is unqualified, the processor 211 also determines whether the maximum deviation value is greater than a second preset threshold. If it is greater than the second preset threshold, one or more target deviation values that are greater than the first preset threshold among the N deviation values are obtained (i.e., all deviation values greater than the first preset threshold are found and taken as the target deviation values). This step helps to identify particularly severe randomization problems.

Through this process, the processor 211 may comprehensively evaluate the quality of randomization of the write data. This method not only considers the overall degree of randomization, but may also identify an abnormal distribution of specific bit states.

The advantages of this embodiment include:

Strong adaptability: It may be applied to different types of flash memory (SLC, MLC, TLC, QLC, etc.).

Accurate assessment: It provides a quantitative assessment of the quality of randomization by calculating specific deviation values.

Multi-level determination: It may classify randomization quality problems in more detail by using a plurality of thresholds.

Problem localization: It may identify which specific states have distribution problems, thereby facilitating targeted optimization.

The randomization verification operation of the present disclosure is further illustrated below using a complete embodiment.

It is assumed that TLC (Triple-Level Cell) flash memory is used, with a preset number of bit states of 8 (N=8), corresponding to 8 states from S0 to S7. Ideally, the baseline percentage value (P_{base}) for each state is 12.5%.

After reading all the memory cells, the processor 211 obtains the following actual state percentages (Px) through statistics:

S0: 13.0%; S1: 11.0%; S2: 12.5%; S3: 13.2%; S4: 12.8%; S5: 11.9%; S6: 13.3%; S7: 12.3%

Next, the processor 211 calculates a deviation value (Δ) for each state, which is an absolute value of a difference between the actual percentage value (the state percentage of each bit state) and the baseline percentage value (i.e., Δ=|Px-P_{base}|): S0: |13.0% - 12.5%| = 0.5%; S1: |11.0% - 12.5%| = 1.5%; S2: |12.5% - 12.5%| = 0%; S3: |13.2% - 12.5%| = 0.7%; S4: |12.8% - 12.5%| = 0.3%; S5: |11.9% - 12.5%| = 0.6%; S6: |13.3% - 12.5%| = 0.8%; S7: |12.3% - 12.5%| = 0.2%.

The processor 211 finds the maximum deviation value (Δmax): Δmax = 0.8% (corresponding to state S6).

It is assumed that the preset first threshold is 1%, then: 0.8% (Δmax) < 1% (the first preset threshold).

Therefore, in this example, the processor 211 determines through the randomization verification operation that the quality of randomization of the write data is qualified. This indicates that although there is a certain deviation between the actual distribution of each state and the ideal uniform distribution, the degree of deviation is within an acceptable range.

If the maximum deviation value exceeds the first preset threshold, the processor 211 will then determine that the quality of randomization is unqualified. For example, if the actual percentage of S1 is changed to 9%, then its deviation value is 3.5%, which exceeds the first preset threshold of 1%, and at this time, the randomization will be determined to be unqualified (did not pass the randomization verification operation).

This rapid detection method may effectively identify states with abnormal distributions, providing a basis for subsequent data processing or hardware adjustments, so as to improve the reliability and performance of the flash memory.

In another embodiment, in a first randomization verification operation, the processor 211 not only determines whether the maximum deviation value exceeds the first preset threshold, but also introduces a second preset threshold for a more detailed assessment. This method may distinguish between a slight randomization failure and a serious circuit design problem. The following uses a specific example to illustrate this advanced verification process:

It is assumed that TLC flash memory is still used, with 1,000,000 memory cells and 8 bit states (S0-S7). The baseline percentage value (P_{base}) is 12.5%. The first preset threshold is set to 1%, and the second preset threshold is set to 2%. After reading all the memory cells, the processor 211 obtains the following actual state percentages (Px): S0: 15.0%; S1: 9.0%; S2: 12.5%; S3: 10.2%; S4: 14.8%; S5: 15.9%; S6: 12.3%; S7: 10.3%.

The processor 211 calculates a deviation value (Δ) for each bit state: S0: |15.0% - 12.5%| = 2.5%; S1: |9.0% - 12.5%| = 3.5%; S2: |12.5% - 12.5%| = 0%; S3: |10.2% - 12.5%| = 2.3%; S4: |14.8% - 12.5%| = 2.3%; S5: |15.9% - 12.5%| = 3.4%; S6: |12.3% - 12.5%| = 0.2%; S7: |10.3% - 12.5%| = 2.2%.

The processor 211 determines the maximum deviation value (Δmax): Δmax = 3.5% (corresponding to state S1).

Since 3.5% > 1% (the first preset threshold), the processor 211 determines that the randomization is unqualified. Next, the processor 211 continues to determine: 3.5% (Δmax) > 2% (the second preset threshold).

Because the maximum deviation value exceeds the second preset threshold, the processor 211 considers that this may represent a serious problem in the circuit design of the flash memory chip. In this case, the processor 211 obtains all states that exceed the first preset threshold (1%): S0 (2.5%), S1 (3.5%), S3 (2.3%), S4 (2.3%), S5 (3.4%), and S7 (2.2%). The processor 211 marks these states as abnormal states for subsequent analysis and optimization.

In contrast, if the maximum deviation value is between the first preset threshold and the second preset threshold, for example, Δmax = 1.5%, the processor 211 will only obtain the current state that exceeds the first preset threshold (S1).

This advanced verification method has the following advantages: it may quickly identify slight randomization failures; it may detect potentially serious circuit design problems. When a serious problem is found, it provides more comprehensive information on abnormal states, facilitating in-depth analysis and targeted improvements. In addition, by distinguishing between different degrees of randomization failures, corresponding processing strategies may be adopted to improve the reliability and performance of the flash memory chip.

In an embodiment, when the processor 211 determines that the randomization of the write data is unqualified, it may take further measures to assist in subsequent circuit design optimization. Specifically, the processor 211 obtains an abnormal bit state corresponding to the maximum deviation value among the N bit states; and records the abnormal bit state. In an embodiment, this record includes one or more of the following: recording a type of the abnormal bit state; recording a positional distribution of the abnormal bit state in the write data; and recording a type of the randomization operation that caused the abnormal bit state.

For example, it is assumed that the write data corresponding to MLC is "11110000", and the calculated state percentages are: 00: 50%, 01: 0%, 10: 0%, 11: 50%, with a maximum deviation value of 25%. It is assumed that the first preset threshold is 5%, then the quality of randomization of the write data is determined to be unqualified.

The processor identifies states "00" and "11" as abnormal bit states because their deviation values (25%) are the largest.

Next, the processor records the following information:

(1) Type of abnormal bit state: 00 and 11;

(2) Positional distribution: 00 is in the second half, and 11 is in the first half;

(3) Type of randomization operation causing the abnormality: for example, it may be caused by a simple bit flipping operation.

It should be noted that the example of recording above is about a test with one threshold. However, corresponding to a test with multi-stage thresholds, the processor 211 may also record corresponding abnormal bit states. Specifically, after determining that the quality of the randomization of the write data is unqualified, if the maximum deviation value is not greater than the second preset threshold, the processor 211 obtains an abnormal bit state corresponding to the maximum deviation value among the N bit states, and records the abnormal bit state. On the other hand, if the maximum deviation value is greater than the second preset threshold, one or more abnormal bit states corresponding to the one or more target deviation values among the N bit states are obtained, and the one or more abnormal bit states are recorded.

In addition, in some extreme cases, such as when the qualities of randomization of all the write data are unqualified, in an embodiment, the processor 211 may further adjust the plurality of randomization operations according to the abnormal bit state to regenerate a new plurality of write data; and again perform the randomization verification operation on each new write data to attempt to obtain the target write data, and then store the target write data into the plurality of target memory cells. The adjustment includes: selecting or combining different randomization algorithms according to the type and distribution of the abnormal bit state; adjusting parameters of each randomization operation, such as a random sequence for an XOR operation, a shift amount for a shift operation, a permutation table for a permutation operation, etc.; and for data parts where abnormalities frequently occur, increasing the complexity or strength of the randomization operation.

For example, continuing with the example above, after recording the relevant information of states "00" and "11" as abnormal bit states, the processor 211 may perform subsequent processing. For example:

(1) Adjust randomization operation: The processor 211 may adopt the following adjustments:

Select a new randomization algorithm, such as introducing an adjustment to the random sequence of the XOR operation or dividing the data into blocks and applying different randomization strategies to different blocks.

(2) Regenerate write data: The processor 211 uses the adjusted randomization operation to regenerate a plurality of write data.

(3) Perform randomization verification again: The processor 211 repeatedly performs the randomization verification operation on each newly generated write data until a qualified target write data is obtained.

(4) Store target write data: The processor 211 stores the target write data that has passed the verification into a plurality of target memory cells.

This method of dynamically adjusting the randomization operation has significant technical effects. By analyzing the abnormal bit state, the processor may select or combine different randomization algorithms in a targeted manner, such as introducing a shift operation or adjusting an XOR sequence. Processing the data in blocks further improves the flexibility and effectiveness of randomization. This adaptive method may not only solve specific problems of insufficient randomization, but also continuously optimize data distribution and improve storage efficiency. The process of repeated verification and adjustment ensures that the finally written data has a high-quality randomness, so as to extend the service life of the storage device, enhance overall performance and reliability, and at the same time reduce the risks of data hotspots and uneven wear.

This embodiment also provides a computer program product, including computer-readable code, or a non-volatile computer-readable storage medium carrying computer-readable code. When the computer-readable code is run in a processor of a storage device, the processor in the storage device executes the steps of the above-mentioned data writing method. The computer program product may be specifically implemented by hardware, firmware, software, or a combination thereof. In an optional embodiment, the computer program product is specifically embodied as a computer storage medium, and in another optional embodiment, the computer program product is specifically embodied as a software product, such as a Software Development Kit (SDK), etc.

The data writing method and its randomization verification operation proposed by the present disclosure have significant technical effects. By performing multiple randomization operations on the write data and executing a corresponding verification process, the method may effectively improve the uniformity of data distribution in a non-volatile memory. Specifically, this method accurately quantifies the quality of data randomization through steps such as calculating bit state percentages, comparing with a baseline percentage value, and determining deviation values. The introduction of a multi-level threshold determination mechanism may not only identify unqualified randomization results, but also distinguish between different degrees of randomization problems. Finally, randomized write data with a qualified quality may be obtained for storing the original data. In particular, the adaptive adjustment mechanism of this method enables the system to adjust the randomization strategy in a targeted manner by recording the type, distribution position of the abnormal bit state, and the randomization operation that caused the abnormality. For example, selecting a new randomization algorithm, adjusting XOR operation parameters, or processing data in blocks according to the abnormal state. This dynamic optimization method ensures that high-quality randomization results may be adaptively generated even when facing complex and variable data patterns.

In addition, the iterative verification mechanism of this method further ensures the quality of randomization of the write data. By repeatedly performing the randomization operation and verification steps until a target write data that meets the requirements is obtained, the method greatly improves the reliability and uniformity of the stored data. This not only optimizes the usage efficiency of the memory cells, but also significantly extends the service life of the storage device, and reduces the risks of data hotspot problems and uneven wear. In summary, the data writing method and the memory controller provided by the present disclosure have significant advantages in terms of improving the quality of data randomization, optimizing storage efficiency, and extending device lifespan. It provides an efficient, reliable, and adaptive solution for the data storage management of non-volatile storage devices.

It will be apparent to those skilled in the art that various modifications and variations may be made to the disclosed embodiments without departing from the scope or spirit of the disclosure. In view of the foregoing, it is intended that the disclosure covers modifications and variations provided that they fall within the scope of the following claims and their equivalents.

What is claimed is:

1. A data writing method, adapted for a rewritable non-volatile memory module having a plurality of memory cells, the method comprising:
obtaining original data from a host system;
performing a plurality of randomization operations on the original data to obtain a plurality of write data;
performing a randomization verification operation on each of the write data to obtain a target write data from the plurality of write data, wherein the quality of randomization of the target write data is determined to be qualified; and
storing the target write data into a plurality of target memory cells among the plurality of memory cells.

2. The data writing method according to claim 1, wherein each randomization operation uses a different randomization algorithm to process the original data, wherein the different randomization algorithms comprise at least one of the following:
an XOR operation, performing an XOR operation on the original data with a plurality of different predefined random sequences;
a shift operation, performing a plurality of different circular shifts or logical shifts on the original data;
a permutation operation, changing the order of bits in the original data according to a plurality of different predefined permutation tables;
a dynamic random seed operation, generating a plurality of different random seeds based on a system time, a data address, or other system variables, and generating the plurality of write data by using the plurality of random seeds and the original data; and
a grouping operation, dividing the original data into a plurality of sub-blocks, and applying different ones of the XOR operation, the shift operation, the permutation operation, and the dynamic random seed operation to the plurality of sub-blocks.

3. The data writing method according to claim 1, wherein step of performing the randomization verification operation on each of the write data comprises:
obtaining a plurality of bit values of the write data, wherein each of the bit values corresponds to one of N bit states, N is 2^{X} and X is the number of bits that each memory cell is configured to store;
obtaining N state percentages of the N bit states corresponding to the write data according to the plurality of bit values; and
obtaining the quality of randomization of the write data according to the N state percentages.

4. The data writing method according to claim 3, wherein step of performing the randomization verification operation on each of the write data further comprises:
obtaining a baseline percentage value based on the N bit states; and
obtaining the quality of randomization of the write data according to the N state percentages and the baseline percentage value.

5. The data writing method according to claim 4, wherein step of performing the randomization verification operation on each of the write data further comprises:
obtaining N deviation values between the N state percentages and the baseline percentage value based on the plurality of bit values;
determining a maximum deviation value among the N deviation values;
if the maximum deviation value is not greater than a first preset threshold, determining that the quality of the randomization of the write data is qualified;
if the maximum deviation value is greater than the first preset threshold, determining that the quality of the randomization of the write data is unqualified.

6. The data writing method according to claim 5, wherein after determining that the quality of the randomization of the write data is unqualified, the method further comprises:
obtaining an abnormal bit state corresponding to the maximum deviation value among the N bit states; and
recording the abnormal bit state.

7. The data writing method according to claim 6, wherein if qualities of randomization of the plurality of write data are all unqualified, the method further comprises:
adjusting the plurality of randomization operations according to the abnormal bit state to regenerate a new plurality of write data; and
again performing the randomization verification operation on each new write data to attempt to obtain the target write data, so as to store the target write data into the plurality of target memory cells.

8. The data writing method according to claim 4, wherein step of performing the randomization verification operation on each of the write data further comprises:
obtaining N deviation values between the N state percentages and the baseline percentage value based on the plurality of bit values;
determining a maximum deviation value among the N deviation values;
if the maximum deviation value is not greater than a first preset threshold, determining that the quality of the randomization of the write data is qualified;
if the maximum deviation value is greater than the first preset threshold, determining that the quality of the randomization of the write data is unqualified, and determining whether the maximum deviation value is greater than a second preset threshold,
wherein if the maximum deviation value is greater than the second preset threshold, obtaining one or more target deviation values that are greater than the first preset threshold among the N deviation values.

9. The data writing method according to claim 8, wherein after determining that the quality of the randomization of the write data is unqualified, the method further comprises:
if the maximum deviation value is not greater than the second preset threshold, obtaining an abnormal bit state corresponding to the maximum deviation value among the N bit states, and recording the abnormal bit state; and
if the maximum deviation value is greater than the second preset threshold, obtaining one or more abnormal bit states corresponding to the one or more target deviation values among the N bit states, and recording the one or more abnormal bit states.

10. A memory controller, adapted for a storage device configured with a rewritable non-volatile memory module, wherein the storage device is electrically connected to a host system, the memory controller comprising:
a memory interface control circuit, for electrically connecting to the rewritable non-volatile memory module, wherein the rewritable non-volatile memory module has a plurality of memory cells; and
a processor, electrically connected to the memory interface control circuit,
wherein the processor is configured to:
obtain original data from the host system;
perform a plurality of randomization operations on the original data to obtain a plurality of write data;
perform a randomization verification operation on each of the write data to obtain a target write data from the plurality of write data, wherein the quality of randomization of the target write data is determined to be qualified; and
store the target write data into a plurality of target memory cells among the plurality of memory cells.

11. The memory controller according to claim 10, wherein each randomization operation uses a different randomization algorithm to process the original data, wherein the different randomization algorithms comprise at least one of the following:
an XOR operation, performing an XOR operation on the original data with a plurality of different predefined random sequences;
a shift operation, performing a plurality of different circular shifts or logical shifts on the original data;
a permutation operation, changing the order of bits in the original data according to a plurality of different predefined permutation tables;
a dynamic random seed operation, generating a plurality of different random seeds based on a system time, a data address, or other system variables, and generating the plurality of write data by using the plurality of random seeds and the original data; and
a grouping operation, dividing the original data into a plurality of sub-blocks, and applying different ones of the XOR operation, the shift operation, the permutation operation, and the dynamic random seed operation to the plurality of sub-blocks.

12. The memory controller according to claim 10, wherein step of performing the randomization verification operation on each of the write data comprises:
obtaining a plurality of bit values of the write data, wherein each of the bit values corresponds to one of N bit states, N is 2^{X} and X is the number of bits that each memory cell is configured to store;
obtaining N state percentages of the N bit states corresponding to the write data according to the plurality of bit values; and
obtaining the quality of randomization of the write data according to the N state percentages.

13. The memory controller according to claim 12, wherein step of performing the randomization verification operation on each of the write data further comprises:
obtaining a baseline percentage value based on the N bit states; and
obtaining the quality of randomization of the write data according to the N state percentages and the baseline percentage value.

14. The memory controller according to claim 13, wherein step of performing the randomization verification operation on each of the write data further comprises:
obtaining N deviation values between the N state percentages and the baseline percentage value based on the plurality of bit values;
determining a maximum deviation value among the N deviation values;
if the maximum deviation value is not greater than a first preset threshold, determining that the quality of the randomization of the write data is qualified;
if the maximum deviation value is greater than the first preset threshold, determining that the quality of the randomization of the write data is unqualified.

15. The memory controller according to claim 14, wherein after determining that the quality of the randomization of the write data is unqualified, the processor is further configured to:
obtain an abnormal bit state corresponding to the maximum deviation value among the N bit states; and
record the abnormal bit state.

16. The memory controller according to claim 15, wherein if qualities of randomization of the plurality of write data are all unqualified, the processor is further configured to:
adjust the plurality of randomization operations according to the abnormal bit state to regenerate a new plurality of write data; and
again perform the randomization verification operation on each new write data to attempt to obtain the target write data, so as to store the target write data into the plurality of target memory cells.

17. The memory controller according to claim 13, wherein step of performing the randomization verification operation on each of the write data further comprises:
obtaining N deviation values between the N state percentages and the baseline percentage value based on the plurality of bit values;
determining a maximum deviation value among the N deviation values;
if the maximum deviation value is not greater than a first preset threshold, determining that the quality of the randomization of the write data is qualified;
if the maximum deviation value is greater than the first preset threshold, determining that the quality of the randomization of the write data is unqualified, and determining whether the maximum deviation value is greater than a second preset threshold,
wherein if the maximum deviation value is greater than the second preset threshold, obtaining one or more target deviation values that are greater than the first preset threshold among the N deviation values.

18. The memory controller according to claim 17, wherein after determining that the quality of the randomization of the write data is unqualified, the processor is further configured to:
if the maximum deviation value is not greater than the second preset threshold, obtain an abnormal bit state corresponding to the maximum deviation value among the N bit states, and record the abnormal bit state; and
if the maximum deviation value is greater than the second preset threshold, obtain one or more abnormal bit states corresponding to the one or more target deviation values among the N bit states, and record the one or more abnormal bit states.
